(19) United States
(12) Patent Application Publication
(10) Pub. No.: US 2007/0221128 A1
(43) Pub. Date: Sep. 27, 2007

(54) Method and apparatus for improving uniformity of large-area substrates

(76) Inventors: Soo Young Choi, Fremont, CA (US); John M. White, Hayward, CA (US)

Correspondence Address: PATTERSON & SHERIDAN, LLP, 3040 POST OAK BOULEVARD, SUITE 1500, HOUSTON, TX, 77056, US

(21) Appl. No.: 11/389,603

(22) Filed: Mar. 23, 2006

(51) Int. Cl. C23C 16/00

(52) U.S. Cl. 118/715

(57) ABSTRACT

Embodiments of the present invention generally provide methods and apparatus for improving the uniformity of a film deposited on a large-area substrate, particularly for films deposited in a PECVD system. In one embodiment, a plasma-processing chamber is configured to be asymmetrical relative to a substrate in order to compensate for plasma density non-uniformities in the chamber caused by unwanted magnetic fields. In another embodiment, a plasma-processing chamber is adapted to create a neutral current bypass path that reduces electric current flow through a magnetic field-generating feature in the chamber. In another embodiment, a method is provided for depositing a uniform film on a large-area substrate in a plasma-processing chamber. The chamber is made electrically symmetric during processing by creating a neutral current bypass path, wherein the neutral current bypass path substantially reduces neutral current flow through a magnetic field-generating feature in the chamber.

### CROSS-REFERENCE TO RELATED APPLICATIONS

This application is a continuation-in-part of co-pending U.S. patent application Ser. No. 11/173,210 [APPM 9230.P02], filed Jul. 1, 2005, which is herein incorporated by reference in its entirety to the extent not inconsistent with the claimed invention.

### BACKGROUND OF THE INVENTION

1. Field of the Invention

Embodiments of the present invention generally relate to deposition of thin films on a large-area substrate.

2. Description of the Related Art

Liquid crystal displays or flat panels are commonly used for active matrix displays such as computer and television monitors. Plasma enhanced chemical vapor deposition (PECVD) is generally employed to deposit thin films on a substrate such as a transparent substrate for flat panel display or semiconductor wafer. PECVD is generally accomplished by introducing a precursor gas or gas mixture into a vacuum chamber that contains a substrate. The precursor gas or gas mixture is typically directed downwardly through a distribution plate situated near the top of the chamber. The precursor gas or gas mixture in the chamber is energized (e.g., excited) into a plasma by applying radio frequency (RF) power to the chamber from one or more RF sources coupled to the chamber. The excited gas or gas mixture reacts to form a layer of material on a surface of the substrate that is positioned on a temperature controlled substrate support. Volatile by-products produced during the reaction are pumped from the chamber through an exhaust system.

Flat panels processed by PECVD techniques are typically large, often exceeding 1 m×1 m. Large area substrates approaching and exceeding 5 square meters are envisioned in the near future. Gas distribution plates, or diffuser plates, utilized to provide uniform process gas flow over flat panels during processing are also relatively large in size, particularly as compared to the gas distribution plates utilized for 200 mm and 300 mm semiconductor wafer processing. “Substrate size” and “diffuser plate size,” as used herein, refer to the nominal surface area, or footprint, of a substrate or diffuser plate and not to the wetted surface area, i.e., the total surface area of all sides and surfaces combined. For example, a 1,000 mm×1,000 mm diffuser plate has a nominal size of 1,000,000 mm², but a much higher wetted surface area, which includes the top and bottom surfaces, side edges, and all features machined into the surface of the diffuser.

As the size of substrates continues to grow, especially when the substrate size is at least about 1300 mm by about 1500 mm (or about 2.0 m²), film thickness uniformity and film property uniformity for large-area, plasma-enhanced chemical vapor deposition (PECVD) becomes more problematic. As used herein, “large-area”, when referring to a substrate, is defined as a substrate of size greater than about 2.0 m². One example of a significant film uniformity problem for large-area substrates occurs during plasma processing in a plasma-processing chamber. In a region of large-area substrates proximal to the slit valve opening of a typical plasma-processing chamber, film thickness and film stress uniformity are known to be consistently unsatisfactory. This is particularly true for the deposition of SiN films, also referred to in the art as a-Si:Nx:H films, on substrates of at least about 2.0 m². SiN films may be used for gate dielectric layers or passivation layers as part of the manufacture of electronic devices. As substrate sizes increase, the non-uniformity of deposited films in the region near the chamber slit valve opening is known to also increase—particularly when process parameters are adjusted to provide the highest quality film. For film thickness and film deposition rate, non-uniformity is defined as:

% Non-Uniformity=(max value−min value)/(max value+min value)×100

### Film properties for which a desired non-uniformity may be required to enable the manufacture of electronic devices include thickness, film stress, Si—H bonding concentration, and electrical resistivity.

FIG. 1A illustrates a three-dimensional map of film thickness uniformity for a SiN film deposited on a 1500 mm×1800 mm rectangular substrate, hereinafter referred to as substrate 1. The contour interval for FIGS. 1A, 1B is 200 Å. Generally for a SiN film, lower Si—H bonding concentration and higher compressive film stress are desirable. Compressive film stress is indicated by negative values. Both of these film properties were measured at three locations (A, B, and C) on substrate 1 and the results are presented in Table 1, below. The locations A, B, and C are indicated on FIGS. 1A, 1B, and 2. Location A corresponds to the edge of substrate 1 closest to the slit valve opening of the plasma-processing chamber. Location B corresponds to the center of substrate 1. Location C corresponds to the edge of substrate 1 farthest from the slit valve opening. Deposition rate of the film deposited on substrate 1 was 2080 Å/min. Film thickness non-uniformity for the substrate 1 is 4.3% and referring to FIG. 1A, the deposited film displays no strong non-uniformity trends. Referring to Table 1, however, compressive film stress is relatively low at location A and at locations B and C the film stress is worse, i.e. tensile. Further, Si—H content for this film is relatively high—12.2%, 15.8%, and 15.1%. In summary, the deposited film is uniform, but has less than ideal film properties.

TABLE 1
Comparison of film properties and non-uniformity of two SiN films.

| | | | | | Non- |
|---|---|---|---|---|---|
| | | Location A | Location B | Location C | Uniformity |
| Substrate 1 | Film Stress | −0.9 | 0.5 | 1.2 | 4.3% |
| | % Si—H Conc. | 12.2 | 15.8 | 15.1 | |
| Substrate 2 | Film Stress | −6.0 | −4.8 | −5.2 | 11.0% |
| | % Si—H Conc. | 6.6 | 8.1 | 8.0 | |

FIG. 1B illustrates a three-dimensional map of film thickness uniformity for a second SiN film deposited on a second 1500 mm×1800 mm rectangular substrate, hereinafter referred to as substrate 2. To provide a higher quality film than the film deposited on substrate 1, i.e. higher compressive film stress and lower Si—H content, process parameters for the second film, such as process gas flow rate, plasma power, and substrate temperature, were optimized. Both film properties were also measured at locations A, B, and C on substrate 2 and the results are presented in Table 1. Substrate 2 was processed in the same plasma-processing chamber as substrate 1. Deposition rate of the film deposited on substrate 1 was 2035 Å/min-essentially the same as the deposition rate for the first film. Referring to Table 1, the film properties for substrate 2 are significantly improved compared to those for substrate 1. Film stress for substrate 2 is highly compressive (between about −5 and −6 E9 dyne/cm²) and Si—H content is approximately half that for substrate 2. Conversely, film thickness uniformity for substrate 2 is much worse—11.0%. Referring to FIG. 1B, the deposited film clearly displays significant thickness non-uniformity near the slit valve opening. Further, referring to Table 1, the Si—H content and film stress are also affected at location A, i.e., near the slit valve opening. Hence, to improve SiN film properties in such a large chamber, there is a direct tradeoff between film property and film thickness uniformity.

With substrates smaller than about 1300 mm×1500 mm, the effects of the slit valve opening on SiN film thickness uniformity and film property uniformity are either substantially undetectable or are avoidable by optimizing process parameters to provide better uniformity. As substrate sizes increase beyond about 2.0 m², uniformity control via process parameter optimization for SiN films becomes increasingly problematic, if not impossible.

Therefore, there is a need for improved methods and apparatus for improving the uniformity of films deposited on large-area substrates in a plasma enhanced chemical vapor deposition (PECVD) system without affecting the quality of the deposited film.

### SUMMARY OF THE INVENTION

Embodiments of the present invention generally provide methods and apparatus for improving the uniformity of a film deposited on a large-area substrate, particularly for films deposited in a PECVD system.

In one embodiment, a plasma-processing chamber is configured to be asymmetrical relative to a substrate in order to compensate for plasma density non-uniformities in the chamber. In one aspect, a diffuser plate is expanded in proximity to a region of a substrate to increase process gas flow to the region and, hence, reduce the plasma power density therein. In another aspect, configuring a diffuser plate with an asymmetrical conductance profile increases process gas flow to a region of a substrate. In another aspect, modifying hollow cathode cavities in the diffuser decreases plasma density in a region of the chamber. In another aspect, a lower region of a plasma-processing chamber is configured to distance a magnetic field-generating feature in the chamber, such as a slit valve opening, from the processing cavity of the chamber.

In another embodiment, a plasma-processing chamber is adapted to create a neutral current bypass path that reduces electric current flow through a magnetic field-generating feature in the chamber. In one aspect, a neutral current bypass path is created during substrate processing by covering a magnetic field-generating feature with a conductive shutter that is substantially parallel to and flush with the inner wall of the chamber. In another aspect, the neutral current bypass path is a vacuum-tight slit valve door that is substantially parallel to and flush with the inner wall of the chamber.

In another embodiment, a method is provided for depositing a uniform film on a large-area substrate in a plasma-processing chamber. The chamber is made electrically symmetric during processing by creating a neutral current bypass path, wherein the neutral current bypass path substantially reduces neutral current flow through a magnetic field-generating feature in the chamber, such as a slit valve opening or other chamber wall penetration. In one aspect, the neutral current bypass path is a conductive shutter that is substantially parallel to and flush with the inner wall of the chamber. In another aspect, the neutral current bypass path is a vacuum-tight slit valve door that is substantially parallel to and flush with the inner wall of the chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates a three-dimensional map of film thickness uniformity for a SiN film deposited on a 1500 mm×1800 mm rectangular substrate.

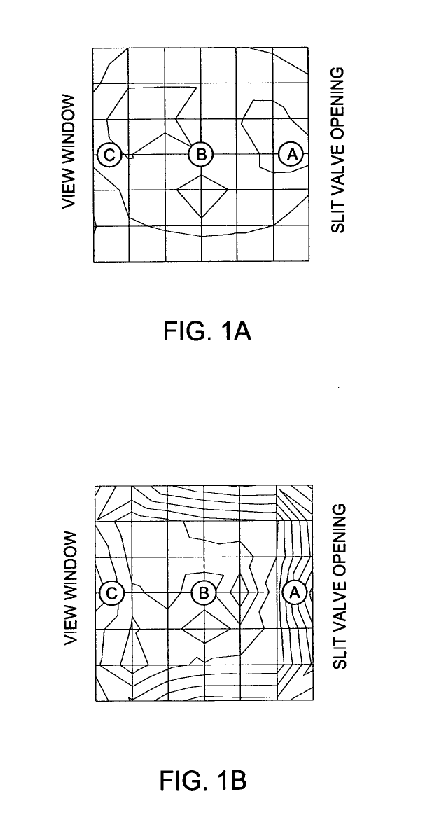

FIG. 1B illustrates a three-dimensional map of film thickness uniformity for a second SiN film deposited on a second 1500 mm×1800 mm rectangular substrate.

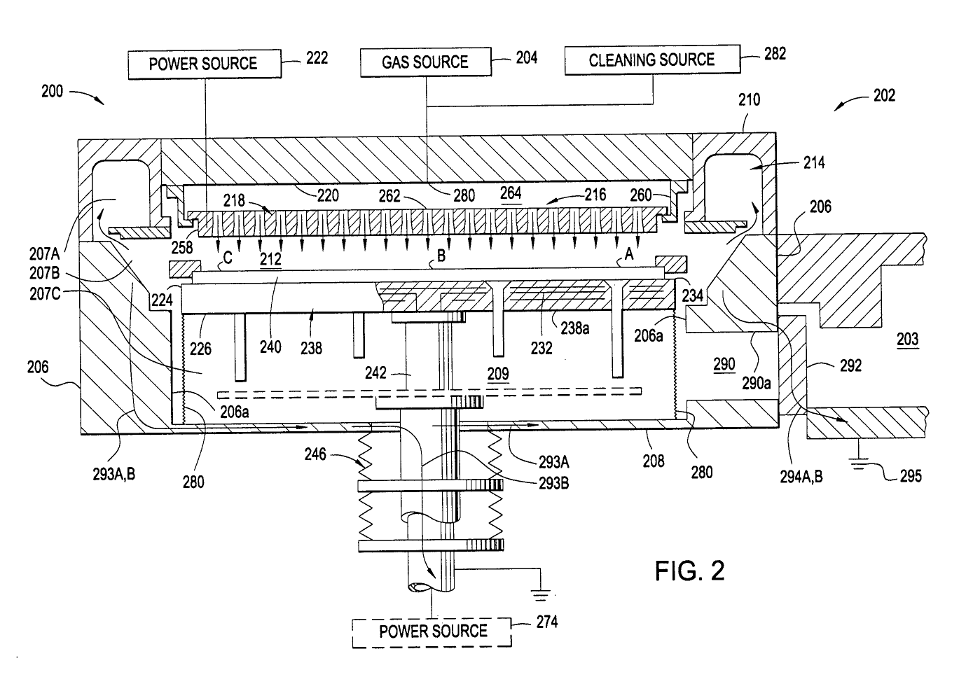

FIG. 2 is a schematic cross-sectional partial view of one embodiment of a plasma enhanced chemical vapor deposition system and chamber that may be adapted to benefit from the invention.

FIG. 2A illustrates a slit valve opening and slit valve door as viewed from a transfer chamber.

FIG. 3A illustrates a schematic plan view of a diffuser plate axi-symmetrically aligned with a substrate.

FIG. 3B illustrates a schematic plan view of a diffuser plate asymmetrically extended relative to a substrate.

FIG. 3C illustrates a schematic plan view of a diffuser plate asymmetrically extended in two regions relative to a substrate.

FIGS. 4A-C illustrate three possible conductance profiles for the gas passages located along a row of gas passages on a diffuser plate.

FIG. 5 illustrates a schematic cross-sectional view of a PECVD processing chamber in which a conductive shutter creates a neutral current bypass path across a slit valve opening.

FIGS. 6A, 6B, and 6C are graphs of the film thickness data measured along each diagonal of three substrates.

FIG. 7 illustrates a schematic cross-sectional view of a PECVD processing chamber, in which the lower chamber is extended a distance from the substrate support assembly.

FIG. 7A (Prior Art) schematically shows an RF hollow cathode and the oscillatory movement of electrons therein between repelling electric fields.

FIG. 8 is a partial sectional view of an exemplary diffuser plate that may be adapted to benefit from the invention.

FIG. 8A illustrates diameter “D”, depth “d” and flaring angle “α” of a bore extending to the downstream end of a gas passage.

For clarity, identical reference numerals have been used, where applicable, to designate identical elements that are common between figures.

### DETAILED DESCRIPTION

The present invention provides methods and apparatus for improving the uniformity of a film deposited on a large-area substrate, particularly for films deposited in a PECVD system.

In one embodiment, a plasma-processing chamber is configured to be asymmetrical relative to a substrate during processing in order to compensate for plasma density non-uniformities in the chamber. In another embodiment, a plasma-processing chamber is adapted to create a neutral current bypass path that reduces electric current flow through a magnetic field-generating feature in the chamber. In another embodiment, a method is provided for depositing a uniform film on a large-area substrate in a plasma-processing chamber. The chamber is made electrically symmetric during processing by creating a neutral current bypass path, wherein the neutral current bypass path substantially reduces neutral current flow through a magnetic field-generating feature in the chamber, such as a slit valve opening or other chamber wall penetration.

As noted above, depositing uniform SiN films for large-area substrates is increasingly problematic due to significant variation occurring in regions of the substrate proximal to a chamber slit valve opening. The uniformity problem is exacerbated by deposition process parameter settings that increase deposition rate, increase the compressive film stress, and decrease Si—H content of the film—all of which are desirable for the manufacture of electronic devices. Further, it has been demonstrated that increasing substrate size and/or plasma power also enhance the non-uniformity effect. Hence, it is highly beneficial for the deposition of SiN films—and potentially for other PECVD-deposited films—to determine a means of improving uniformity without compromising film quality.

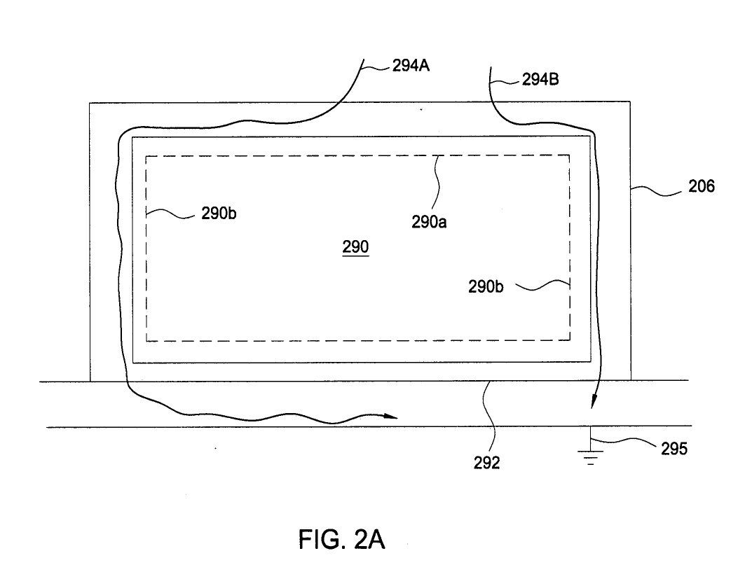

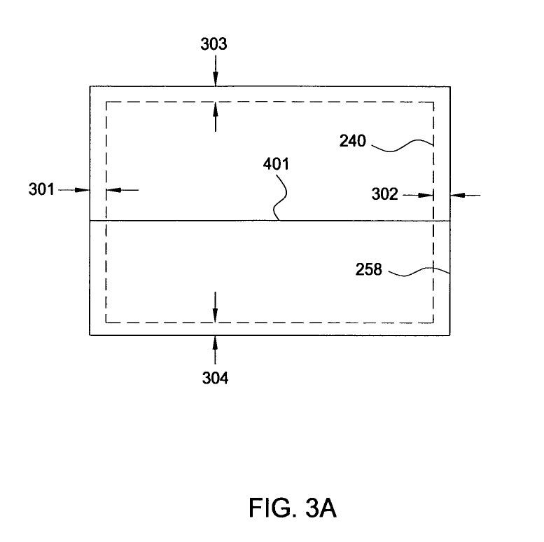

FIG. 2 is a schematic cross-sectional view of one embodiment of a plasma enhanced chemical vapor deposition system 200 that may be adapted to benefit from the invention. PECVD system 200 is available from AKT, a division of Applied Materials, Inc., Santa Clara, Calif. The PECVD system 200 generally includes at least one processing chamber 202 coupled to a gas source 204 and a transfer chamber 203. Typically, processing chamber 202 is directly attached to transfer chamber 203 and may be in fluid communication with transfer chamber 203 via slit valve opening 290. The processing chamber 202 has walls 206, a chamber floor 208, and a lid assembly 210 that substantially define a vacuum region 207A, 207B, 207C. The vacuum region 207A, 207B, 207C includes a lower chamber 209, a processing cavity 212, a pumping plenum 214, and a process gas plenum 264. The lower chamber 209 is defined by chamber floor 208, the lower surface 238a of substrate support assembly 238, and the inner surfaces 206a of the walls 206. Processing cavity 212 is defined by gas distribution plate assembly 218, substrate support assembly 238, and pumping plenum 214. Processing cavity 212 is typically accessed through a slit valve opening 290 in the walls 206 which allows movement of a substrate 240 into and out of the processing chamber 202 from transfer chamber 203 of PECVD system 200. Typically a slit valve door 292 is used to isolate processing chamber 202 from the environment outside slit valve opening 290 with a vacuum-tight seal. The walls 206 and chamber floor 208 may be fabricated from a unitary block of aluminum or other material compatible with processing. The walls 206 support lid assembly 210. Lid assembly 210 contains pumping plenum 214, which couples the processing cavity 212 to an exhaust port (not shown) for removing process gases and processing byproducts from processing cavity 212. Alternatively, an exhaust port may be located in chamber floor 208 of processing chamber 202, in which case pumping plenum 214 is not required for processing cavity 212.

The lid assembly 210 typically includes an entry port 280 through which process gases provided by the gas source 204 are introduced into the processing chamber 202. The entry port 280 is also coupled to a cleaning source 282. The cleaning source 282 typically provides a cleaning agent, such as dissociated fluorine, that is introduced into the processing chamber 202 to remove deposition by-products and films from processing chamber hardware, including the gas distribution plate assembly 218.

The gas distribution plate assembly 218 is coupled to an interior side 220 of the lid assembly 210. The shape of gas distribution plate assembly 218 is typically configured to substantially conform to the perimeter of the glass substrate 240, for example, polygonal for large area flat panel substrates and circular for wafers. The gas distribution plate assembly 218 includes a perforated area 216 through which process and other gases supplied from the gas source 204 are delivered to the processing cavity 212. The perforated area 216 of the gas distribution plate assembly 218 is configured to provide uniform distribution of gases passing through the gas distribution plate assembly 218 into the processing chamber 202. Gas distribution plates that may be adapted to benefit from the invention are described in commonly assigned U.S. patent application Ser. No. 09/922,219, filed Aug. 8, 2001 by Keller et al., U.S. patent application Ser. No. 10/140,324, filed May 6, 2002 by Yim et al., and Ser. No. 10/337,483, filed Jan. 7, 2003 by Blonigan et al., U.S. Pat. No. 6,477,980, issued Nov. 12, 2002 to White et al., U.S. patent application Ser. No. 10/417,592, filed Apr. 16, 2003 by Choi et al., and U.S. patent application Ser. No. 10/823,347, filed on Apr. 12, 2004 by Choi et al., which are hereby incorporated by reference in their entireties.

The gas distribution plate assembly 218 typically includes a diffuser plate (or distribution plate) 258 suspended from a hanger plate 260. The diffuser plate 258 and hanger plate 260 may alternatively comprise a single unitary member. A plurality of gas passages 262 are formed through the diffuser plate 258 to allow a predetermined distribution of gas to pass through the gas distribution plate assembly 218 and into the processing cavity 212. A process gas plenum 264 is formed between hanger plate 260, diffuser plate 258 and the interior surface 220 of the lid assembly 210. The process gas plenum 264 allows gases flowing through the lid assembly 210 to uniformly distribute across the width of the diffuser plate 258 so that gas is provided uniformly above the center perforated area 216 and flows with a uniform distribution through the gas passages 262.

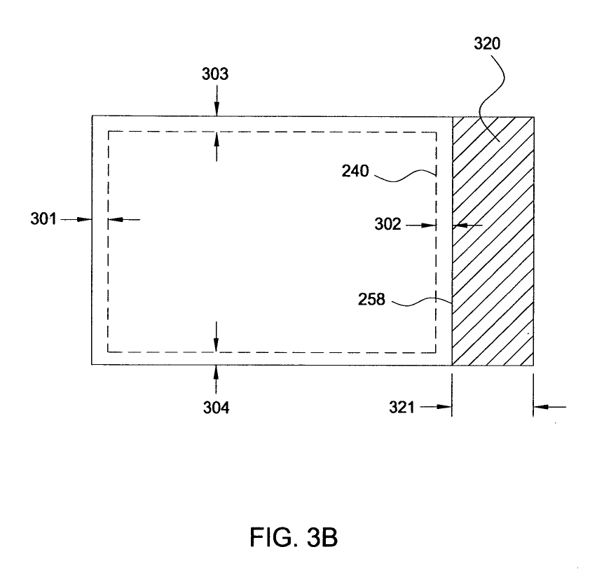

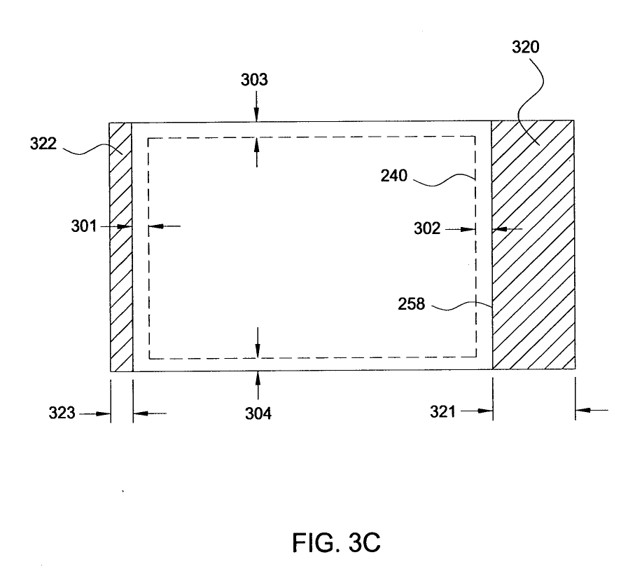

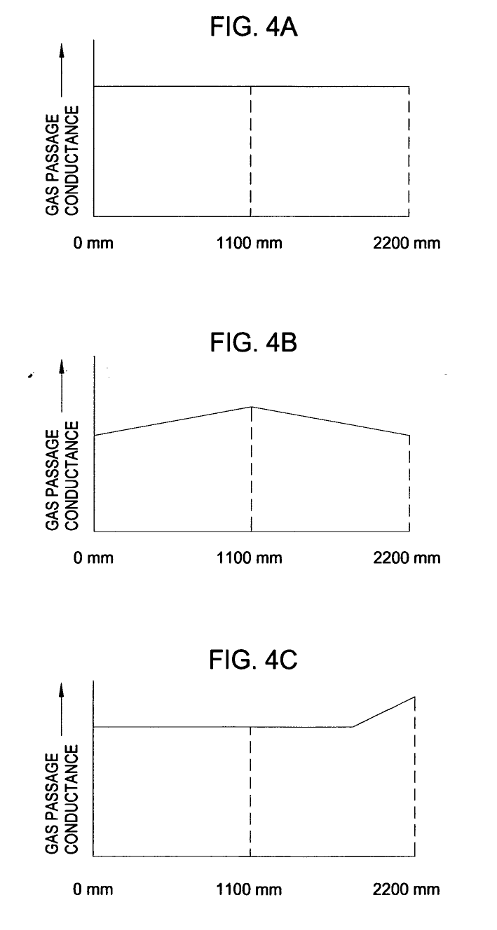

It has been standard practice in the art for diffuser plate 258 to not only conform to the perimeter of the glass substrate 240, but also to be aligned axi-symmetrically with glass substrate 240, as illustrated in FIG. 3A. When processing substrates smaller than large-area substrates, this minimizes film non-uniformity near edges of the substrate. FIG. 3A illustrates a schematic plan view of a diffuser plate 258 axi-symmetrically aligned with a substrate 240. Because diffuser plate 258 is typically over-sized relative to substrate 240, diffuser plate 258 overhangs substrate 240 on all sides. In the art, it is standard practice for diffuser plate 258 to be axi-symmetrically aligned with substrate 240. Hence, overhang 301 is substantially equal to overhang 302 and overhang 303 is substantially equal to overhang 304. In contrast, aspects of the invention contemplate a plasma-processing chamber wherein the diffuser is configured asymmetrically relative to the substrate, as described below in conjunction with FIGS. 3B and 3C.

Substrate support assembly 238 may be temperature controlled and is centrally disposed within the processing chamber 202. The substrate support assembly 238 supports a glass substrate 240 during processing. In one embodiment, the substrate support assembly 238 comprises an aluminum body 224 that encapsulates at least one embedded heater 232. The heater 232, such as a resistive element, disposed in the substrate support assembly 238, is coupled to an optional power source 274 and controllably heats the substrate support assembly 238 and the glass substrate 240 positioned thereon to a predetermined temperature. Typically, in a CVD process, the heater 232 maintains the glass substrate 240 at a uniform temperature between about 150° C. to at least about 460° C., depending on the deposition processing parameters for the material being deposited.

Generally, the substrate support assembly 238 has a lower side 226 and an upper side 234. The upper side 234 supports the glass substrate 240. The lower side 226 has a stem 242 coupled thereto. The stem 242 couples the substrate support assembly 238 to a lift system (not shown) that moves the substrate support assembly 238 between an elevated processing position (as shown) and a lowered position that facilitates substrate transfer to and from the processing chamber 202. The stem 242 additionally provides a conduit for electrical and thermocouple leads between the substrate support assembly 238 and other components of the PECVD system 200.

A bellows 246 is coupled between substrate support assembly 238 (or the stem 242) and the chamber floor 208 of the processing chamber 202. The bellows 246 provides a vacuum seal between the processing cavity 212 and the atmosphere outside the processing chamber 202 while facilitating vertical movement of the support assembly 238.

The substrate support assembly 238 generally is grounded such that radio frequency (RF) power supplied by a power source 222 to gas distribution plate assembly 218—or other electrode positioned within or near the lid assembly of the chamber—may excite gases present in the processing cavity 212, i.e., between the substrate support assembly 238 and the distribution plate assembly 218. The RF power from power source 222 is generally selected commensurate with the size of the substrate to drive the chemical vapor deposition process. Larger substrates require higher magnitude RF power for PECVD processing, resulting in larger currents, including the higher voltage current flowing to the gas distribution plate assembly 218 and the low voltage current flowing from the processing cavity 212 back to ground or neutral in order to complete the electrical circuit of the plasma generation

In an exemplary PECVD process, a 1870 mm×2200 mm substrate is transferred into processing chamber 202 from transfer chamber 203 by a substrate-handling robot (not shown) and placed on substrate support assembly 238. Process gases are introduced from gas source 204 into gas plenum 264, which then flow into processing cavity 212. In this example, between about 1000-9000 sccm of SiH₄, 10,000-50,000 sccm NH₃, and 20,000-120,000 sccm N₂ are used. Plasma is then created in processing cavity 212 and deposition of a SiN film takes place on the substrate. The electrode spacing, i.e., the distance between the gas diffuser plate and the substrate support in the PECVD chamber, is between about 0.400 inches and about 1.20 inches while depositing the film. Other process conditions during deposition of the film are: 5-30 kW RF plasma power, chamber pressure of 0.7-2.5 Torr, and substrate temperature of 100-400° C.

Referring to FIGS. 2 and 2A, neutral current return paths 293A, 293B indicates the neutral current flow through a wall 206 that is without any features that may generate a significant magnetic field. The neutral current, i.e., the current flowing from processing cavity 212 back to ground to complete the electrical circuit, flows down wall 206, along chamber floor 208, and then back to ground or neutral through stem 242 and/or through transfer chamber 203, via ground path 295. Conversely, neutral current return paths 294A, 294B indicate the neutral current flow through a wall 206 that does have a feature that may generate a magnetic field when a significant electric current passes therethrough. In this case, the magnetic field-generating feature is slit valve opening 290. Along neutral current return paths 294A, 294B, the neutral current flows down wall 206, along upper surface 290a, then through slit valve door 292 and/or the sidewalls 290b of slit valve opening 290. For clarity, sidewalls 290b of slit valve opening 290 are only depicted in FIG. 2A. FIG. 2A illustrates slit valve opening 290 and slit valve door 292 as viewed from transfer chamber 203.

It is believed that, with the large powers associated with PECVD for large-area substrates, e.g. 10-20 kW, the current flowing via neutral current return paths 294A, 294B may generate a magnetic field of an intensity capable of substantially effecting the plasma in processing cavity 212 of chamber 202. As used herein, “substantially effecting plasma” when referring to a magnetic field, is defined as intensifying or altering a plasma sufficiently to result in a measurable, repeatable, and predictable change in process results, e.g. film uniformity reduction. There are numerous sources of extraneous magnetic fields that may theoretically effect process results including the earth's, those generated by current flow to and from adjacent substrate processing equipment, etc. However, none of these sources have been shown to “substantially effect” film uniformity of large-area substrates on the order found to be the case with the magnetic field associated with neutral current return paths.

Table 2 summarizes a comparison of SiN films deposited on three substrates, illustrating the trade-off between film uniformity and film quality for a 2200 mm×1870 mm. The film stress, Si—H content, and thickness non-uniformity of three substrates (substrates 4, 5, and 6) are compared. All three substrates were processed in the same PECVD chamber at the same deposition rate, but process parameters were varied for each substrate in order to deposit a slightly different film on each. Substrate 4 demonstrates that, for a substrate of this size, a relatively uniform film, i.e. non-uniformity of 8.4%, may be deposited, but the Si—H concentration and compressive film stress are relatively poor. Conversely, substrate 6 demonstrates that a low Si—H, high compressive stress film can only be deposited with poor thickness non-uniformity, i.e., 31%. Comparing Tables 1 and 2, it can also be seen that the non-uniformity issue is also exacerbated as substrate size increases.

TABLE 2
Comparison of film properties and non-uniformity of three SiN films.

| | | Si—H | |
|---|---|---|---|
| | Film Stress | Conc. | Non-Uniformity |
| Substrate | (E9 dyne/cm²) | (%) | (%) |
| 4 | −0.2 | 12.1 | 8.4 |
| 5 | −2.8 | 13.3 | 18.0 |
| 6 | −5.2 | 2.2 | 31.1 |

Similar trends have been demonstrated with increasing RF plasma power. For example, when depositing a SiN film on a 2200 mm×1870 mm substrate, the thickness non-uniformity increases greatly from 10.8% to 14.0% when RF plasma power is only increased from 18 kW to 19 kW, implying that RF plasma power is closely related to the root cause of the local non-uniformity.

Based on empirical evidence as well as numerous trouble-shooting tests, it is believed that the uniformity of plasma density in the processing cavity of PECVD chambers for large-area substrates is degraded by unwanted magnetic fields generated in or near the chamber during processing. These magnetic fields are generated by neutral current return paths along the surface of the chamber that disrupt the electrical symmetry of the chamber, such as those along the top and sidewalls of the slit valve opening.

Evidence of the presence of plasma in and around the slit valve opening for large-area substrate PECVD chambers is known and numerous tests, detailed below, have been conducted to eliminate such unwanted plasma as well as the non-uniformity of SiN films. In addition, the non-uniformity effect is currently observable on PECVD SiN films and not on amorphous films. It is known in the art that SiN film uniformity is generally more sensitive to variations in plasma density than amorphous silicon films, indicating that changes in plasma density uniformity in the processing cavity are responsible for the SiN film non-uniformity occurring proximal the slit valve opening. Further, the high sensitivity of film uniformity to RF power implies that stronger electrical currents, such as the neutral currents generated during substrate processing, are responsible for the increase in plasma density near the slit valve opening. The most likely mechanism therefore is magnetic field generation by the neutral currents.

Test 1: Referring to FIG. 2, in one experiment, a grounding curtain 280 was installed inside lower chamber 209 around the substrate support assembly 238 to act as plasma shielding and prevent plasma from “leaking” out of processing cavity 212. This did not improve SiN film non-uniformity, indicating that plasma “leakage” from process cavity 212 is not the issue. It is important to note that grounding curtain 280 would not affect a surface current that is generating the plasma in the slit valve opening.

Test 2: Asymmetrical pumping of gases from processing cavity 212 was used to increase the process gas density locally in the region of processing cavity 212 nearest slit valve opening 290. Increasing process gas density decreases the power density, i.e. the amount of power generated per unit of process gas flow. This was intended to compensate for the unwanted higher plasma density present in the region of processing cavity 212 nearest slit valve opening 290. Altering the symmetrical pumping of process gases from processing cavity 212 through pumping plenum 214 did not significantly alter the uniformity of process gas density in processing cavity 212 and, hence, did not affect SiN film non-uniformity.

Test 3: In another attempt to compensate for plasma density non-uniformity by altering the plasma density locally in processing cavity 212, the RF power connection to diffuser plate 258 was relocated. No improvement was observed in SiN film non-uniformity, therefore this approach had little or no effect on plasma density uniformity in processing cavity 212.

Test 4: In another effort to reduce the plasma density locally in processing cavity 212, process gas flow into process gas plenum 264 was relocated. No significant improvement in SiN film non-uniformity was detected. Because the change to the process gas flow was made upstream of diffuser plate 258, which is designed to equalize gas flow entering processing cavity 212, no significant change to the plasma density was realized. To effect significant change in plasma density in processing cavity 212, the process gas uniformity must be more aggressively altered.

Test 5: In yet another test, process chamber 202 was electrically isolated from transfer chamber 203 to eliminate the magnetic field generated by the neutral current flowing along neutral current return paths 294A, 294B. No improvement to SiN film non-uniformity was observed. Therefore, isolating neutral current return paths 294A, 294B from ground path 295 does not alter neutral current flow along neutral current return paths 294A, 294B, only their final destination.

The above observations and tests underscore two important facts. First, that plasma—and therefore a magnetic field—is being generated in the slit valve opening. Neutral current flowing along surfaces of the slit valve opening causes this. Second, that in order to compensate for the locally higher plasma density that results from the unwanted magnetic field, relatively aggressive changes to local plasma conditions should be made.

As described above, the presence of unwanted magnetic fields in proximity to the processing cavity of a PECVD chamber may increase the plasma power density, resulting in film non-uniformities. One embodiment of the invention contemplates compensating for regions of higher plasma density in a PECVD processing chamber's processing cavity with an asymmetric diffuser plate configuration.

In one aspect, a diffuser plate is not axi-symmetrically aligned with the substrate and instead is asymmetrically extended relative to a substrate to obtain a desired film uniformity on the substrate. FIG. 3B illustrates a schematic plan view of a diffuser plate 258 asymmetrically extended a distance 321 in a region 320 relative to a substrate 240. In this example, diffuser plate 258 is axi-symmetrically aligned with substrate 240 except for region 320. Hence, as in FIG. 3A, overhang 301 is substantially equal to overhang 302 and overhang 303 is substantially equal to overhang 304. By extending diffuser plate 258, a significantly higher process gas flow is introduced in the region of a processing cavity exposed to unwanted magnetic fields. As noted above, higher process gas flow results in a lower plasma power density, reducing or eliminating the film non-uniformity caused by locally higher plasma power density. In other examples of this aspect, diffuser plate 258 may be extended relative to other regions of substrate 240 in order to compensate for unwanted magnetic fields generated by neutral current flow through features of a PECVD chamber besides the slit valve opening, such as the view window penetration, for example. FIG. 3C illustrates a schematic plan view of a diffuser plate 258 asymmetrically extended a distance 321 in a region 320 and a distance 323 in region 322 relative to a substrate 240. Region 320 corresponds to the region of a processing cavity exposed to unwanted magnetic fields generated in a slit valve opening of a PECVD chamber. Region 322 corresponds to the region of a processing cavity exposed to unwanted magnetic fields generated in the view window opening of a PECVD chamber. Region 322 is proportionately smaller than region 320 in view of the substantially weaker magnetic field generated in the view window.

The magnitudes of distances 321 and 323 are proportional to the intensity of the unwanted magnetic fields they are intended to counteract. For example, for a PECVD chamber designed for depositing SiN on a 2200 mm×1870 mm using an RF power of between about 15 kW and about 20 kW, the diffuser plate should be extended a distance 321 of about 450 mm to about 600 mm, or about 30% to about 40% of the diffusers characteristic length. For purposes of determining distance 321 for diffuser plates of different shapes, the characteristic length is considered to be the “equivalent radius”. For a circular diffuser plate, the equivalent radius is equal to the radius of the diffuser plate. For a square or rectangular diffuser plate, the equivalent radius is one half the diagonal.

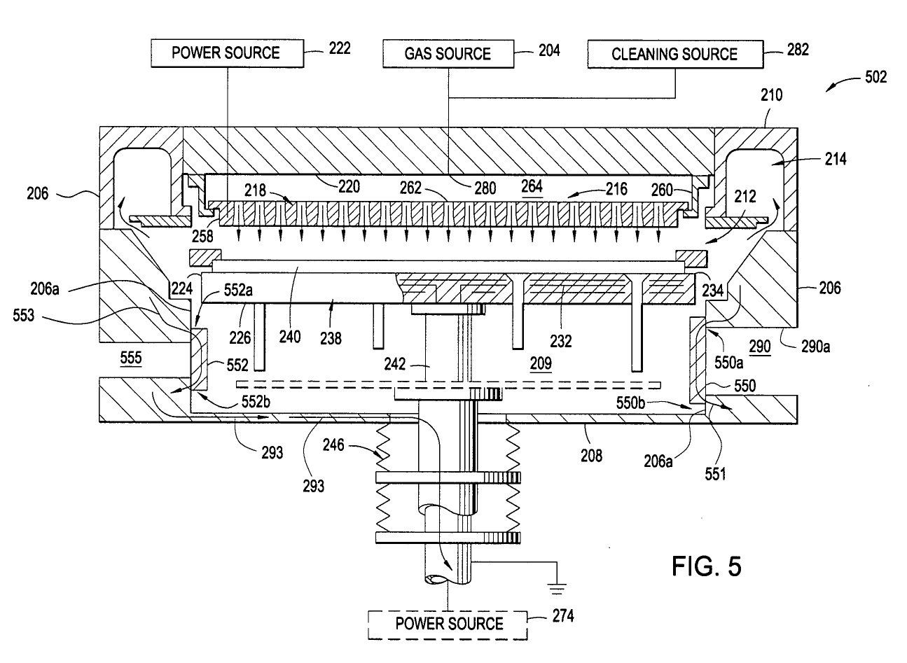

In another aspect, a diffuser plate includes gas passages with an asymmetrical conductance profile to increase the flow of process fluids to a region in a PECVD chamber to improve deposited film uniformity. The term “conductance profile”, as used herein, refers to the conductance of gas passages in a diffuser plate as a function of gas passage location on the diffuser plate. FIGS. 4A-C illustrate three possible conductance profiles for the gas passages located along row 401 of gas passages of diffuser plate 258 illustrated in FIG. 3A. The abscissa of FIGS. 4A-C represents position along line 401 and the ordinate represents gas passage conductance. It is known in the art that for optimal uniformity the conductance profile of a diffuser plate's gas passages should be axially symmetric, as illustrated in FIGS. 4A and 4B. Although the conductance of gas passages along line 401 is not necessarily constant along the length of diffuser plate 258, as illustrated in FIG. 4B, the conductance of gas passages at one edge of diffuser plate 258 mirrors the conductance of gas passages at the opposite edge of diffuser plate. However, for deposition onto large-area substrates, and particularly for deposition of SiN onto large-area substrates, a symmetrical conductance profile may not be beneficial for film uniformity.

In order to compensate for the increased plasma density present in a region of a processing cavity proximal to the slit valve opening, this aspect contemplates an asymmetrical conductance profile, such as that illustrated in FIG. 4C. In the region of the diffuser plate corresponding to poor film uniformity, the conductance of the diffuser's gas passages has been increased. The higher process gas flow rate resulting thereby reduces the plasma power density locally in the processing cavity and improves film uniformity. Deposited film uniformity is highly dependent on a number of process parameters, including deposition rate, plasma power, spacing between diffuser plate and substrate support, substrate support temperature, process gas flow rates, substrate size, and the magnitude of unwanted magnetic fields. Because of this, modifications to a diffuser plate conductance profile are strongly dependent on the particular process being modified. As a first order estimate, conductance of gas passages may be increased proportionally to the film thickness variation in any given region of a substrate. For example, if regions of a deposited film are repeatably 5% too thick, increasing gas passage conductance in that region by about 5% is a good initial estimate. One skilled in the art, upon reading the disclosure herein, can calculate an equivalent gas passage conductance when the local film thickness non-uniformity is different from the local film thickness non-uniformity discussed herein.

In yet another aspect of using an asymmetric diffuser plate configuration to correct deposited film non-uniformity, the size, shape, or frequency of occurance of hollow cathode cavities on the surface of a diffuser plate may varied. Asymmetrical hollow cathode cavity variation may be used to compensate for regions of higher plasma density in a PECVD processing chamber's processing cavity.

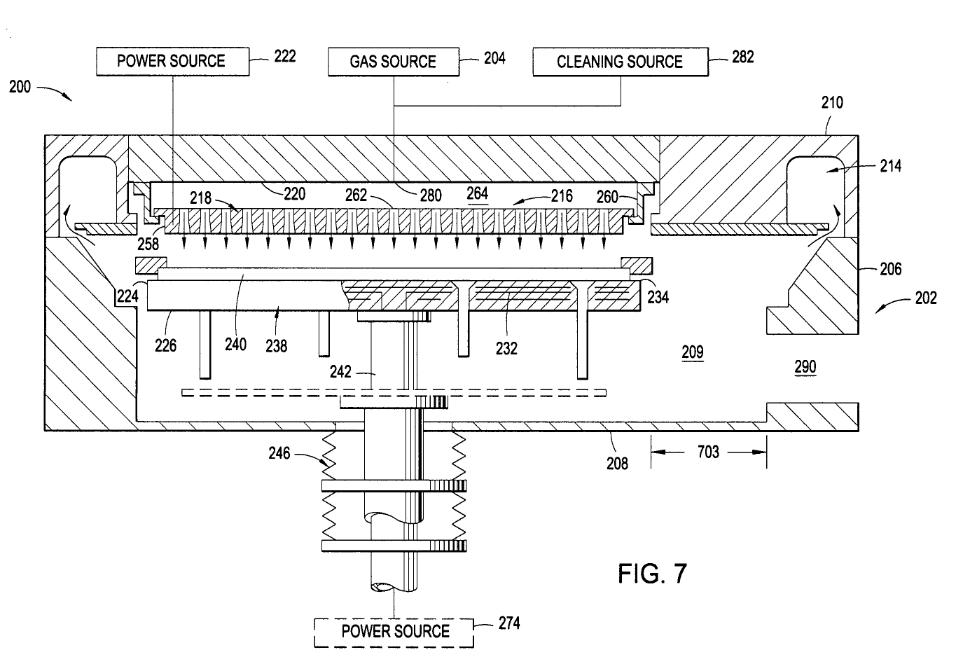

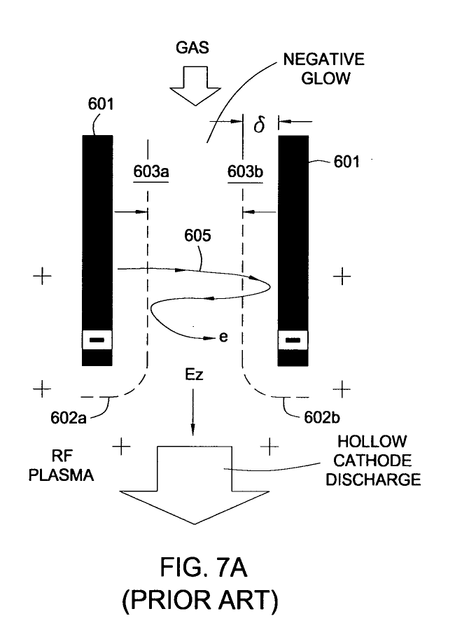

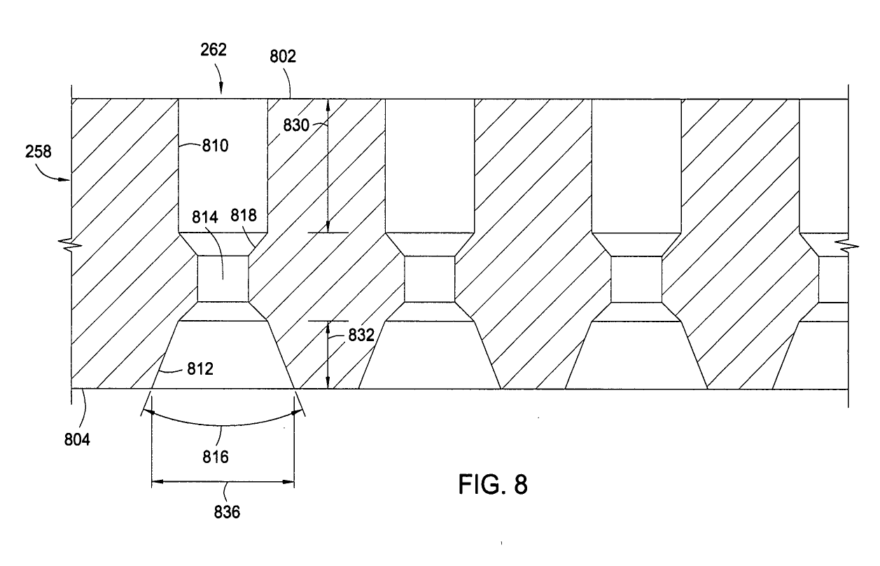

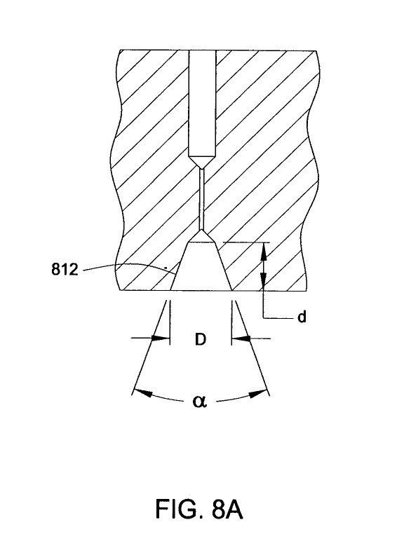

It has been shown that for a SiN film deposited on a substrate larger than about 1,200,000 mm in a PECVD chamber, the film thickness and film property uniformity can be altered by varying the hollow cathode cavities on a diffuser plate, i.e., using a hollow cathode gradient, or HCG. The HCG method is described below in conjunction with FIGS. 7A, 8 and 8A, and in previously referenced U.S. patent application Ser. No. 10/889,683, entitled “Plasma Uniformity Control By Gas Diffuser Hole Design.” Referring back to FIG. 2, a diffuser plate 258 that is configured with HCG may alter the uniformity of a deposited SiN film's thickness and film properties by altering the plasma distribution in process volume 212. This is because deposition of films by PECVD depends substantially on the source of the active plasma. Hence, much like an asymmetrical conductance profile, non-uniform variation in HCG may be used to compensate for non-uniform plasma distribution already present in process volume 212 due to unwanted magnetic fields. This in turn may improve film uniformity on the substrate 240.

Dense chemically reactive plasma can be generated in process volume 212 of PECVD system 200 due to the hollow cathode effect, described here in conjunction with FIG. 7A. The driving force in the RF generation of a hollow cathode discharge of a negatively charged RF electrode 601 is the frequency modulated DC voltage Vₛ, known as the self-bias voltage, across the space charge sheath 602a or 602b at the RF electrode 601. FIG. 7A schematically shows an RF hollow cathode and the oscillatory movement of electrons, “δ”, between repelling electric fields, 603a and 603b, of the opposing sheaths 602a and 602b, respectively. The thickness of wall sheaths 602a and 602b is equal to thickness “δ”. Electron “e” is emitted from the cathode wall, in this case electrode 601, which could be the walls of a gas passage 262 that is close to the process volume 212. Gas passage 262 and process volume 212 are shown in FIGS. 2 and 8. Referring again to FIG. 7A, electron “e” is accelerated by the electric field 603a across the wall sheath 602a. Electron “e” oscillates along path 605 across the inner space between walls of the electrode 601 owing to the repelling fields of opposite wall sheath 602a and 602b. Electron “e” loses energy by collisions with the process gas and creates more ions. The created ions can be accelerated to the cathode walls 601, thereby enhancing emissions of secondary electrons, which could create additional ions. Overall, the cavities between the cathode walls enhance the electron emission and ionization of the gas. Cone frustum-shaped features in the cathode walls, such as when the gas passages formed in the diffuser plate with a gas inlet diameter smaller than the gas outlet diameter, are more efficient in ionizing the gas than cylindrical walls. An example of a cone frustum-shaped cathode cavity is described in more detail below in conjunction with FIG. 8. The potential Ez is created due to the difference in ionization efficiency between the gas inlet and gas outlet.

For diffuser plate 258, the hollow cathode cavities are located on the downstream ends of gas passages 262 and are close to the process volume 212. It has been shown that by changing the design of the walls of the cathode cavities of gas passages 262 and the arrangement or density of the hollow cathode cavities, the gas ionization may be modified to control plasma density and, hence, the film thickness and property uniformity of a deposited SiN film. The methods and results that prove this are described in previously referenced U.S. patent application Ser. No. 10/889,683, entitled “Plasma Uniformity Control By Gas Diffuser Hole Design.” An example of hollow cathode cavities that are close to the process volume 212 is the second bore 812 of FIG. 8. The hollow cathode effect mainly occurs in the cone frustum-shaped region of second bore 812 that faces the process volume 212. The FIG. 8 design is merely used as an example. The invention can be applied to other types of hollow cathode cavity designs. By varying the volume and/or the surface area of the hollow cathode cavity, i.e. second bore 812, the plasma ionization rate can be varied.

FIG. 8 is a partial sectional view of an exemplary diffuser plate 258 that may be adapted to benefit from the invention and is described in commonly assigned U.S. patent application Ser. No. 10/417,592, titled “Gas Distribution Plate Assembly for Large Area Plasma Enhanced Chemical Vapor Deposition”, filed on Apr. 16, 2003, which is hereby incorporated by reference in its entirety to the extent not inconsistent with the claimed invention. The diffuser plate 258 includes a first or upstream side 802 facing the lid assembly 210 and an opposing second or downstream side 804 that faces the support assembly 238. Each gas passage 262 is defined by a first bore 810 coupled by an orifice hole 814 to a second bore 812 that combine to form a fluid path through the gas distribution plate 258. The first bore 810 extends a first depth 830 from the upstream side 802 of the gas distribution plate 258 to a bottom 818.

Using the design in FIG. 8 as an example, the volume of second bore (or hollow cathode cavity) 812 can be changed by varying the diameter “D” (or opening diameter 836 in FIG. 8), the depth “d” (or length 832 in FIG. 8) and the flaring angle “α” (or flaring angle 816 of FIG. 8), as shown in FIG. 8A. Changing the diameter, depth and/or the flaring angle would also change the surface area of the bore 812. By reducing the bore depth, the diameter, the flaring angle, or a combination of these three parameters in a particular region of a diffuser plate, the plasma density can be reduced locally in order to compensate for the effect of unwanted magnetic fields caused by neutral currents and other sources. Methods and results that indicate this are described in previously referenced U.S. patent application Ser. No. 10/889,683, entitled “Plasma Uniformity Control By Gas Diffuser Hole Design.” In this way, SiN film non-uniformity may be reduced when unwanted magnetic fields are present during substrate processing.

Hence, different aspects of the invention involving altering diffuser plate configuration include asymmetrically extending the diffuser plate, varying the conductance profile of a diffuser plate, and varying the hollow cathode or hollow cathode gradient. Advantages of an asymmetric diffuser plate configuration include a significantly broadened process window for deposited films, i.e. a more robust deposition process, and an ability to precisely tune a diffuser plate to provide highly uniform films.

Another embodiment contemplates correction of film non-uniformity issues caused by unwanted magnetic fields by configuring the chamber to be electrically symmetric and/or by reducing the magnitude of unwanted magnetic fields near the processing cavity during processing.

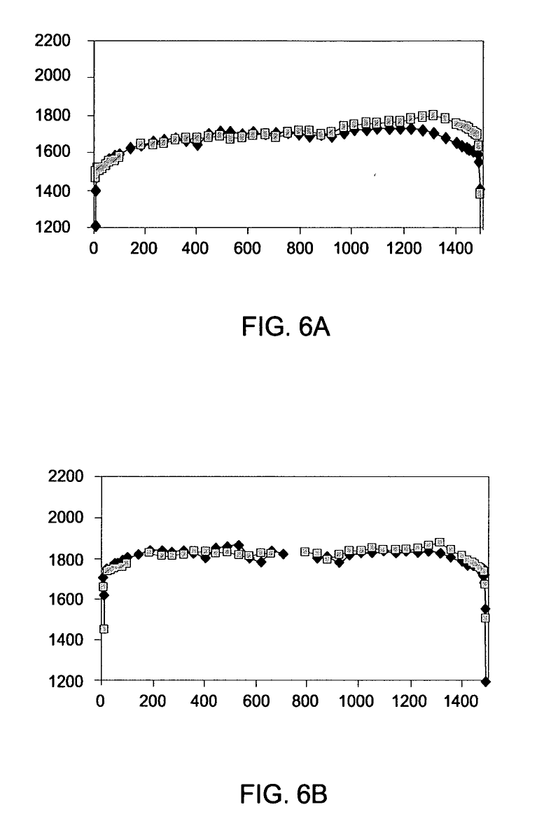

In one aspect, a conductive shutter creates a neutral current bypass path after placing the substrate on the substrate support and prior to creating a plasma. The neutral current bypass path substantially reduces neutral current flow through a magnetic field-generating feature, such as a slit valve opening. FIG. 5 illustrates a schematic cross-sectional view of a PECVD processing chamber, processing chamber 502, in which a conductive shutter 550 creates a neutral current bypass path 551 across a slit valve opening 290. After a substrate 240 is placed in processing chamber 502 and prior to substrate processing, conductive shutter 550 is deployed in the position shown in FIG. 5. In placing conductive shutter 550 over slit valve opening 290 and by establishing solid electrical contact at locations 550a and 550b, neutral current bypass path 551 is created. In this aspect, it is not necessary for conductive shutter 550 to form a vacuum-tight seal across slit valve opening 290. Instead, the magnetic field generated from slit valve opening 290 is reduced during processing by providing an additional neutral current path, i.e. neutral current bypass path 551, through which neutral current may flow instead of along neutral current return paths 294A, 294B (illustrated in FIG. 2). The distribution of current flowing to ground via neutral current bypass path 551 compared to neutral current return paths 294A, 294B are inversely proportional to the resistivity of each current path relative to each other. Hence, when neutral current bypass path 551 has a resistivity significantly less than neutral current return paths 294A, 294B, the majority of neutral current flows along neutral current bypass 551 and any magnetic field generated by slit valve opening 290 is greatly reduced. It is important to note that preferably the neutral current bypass path 551 is substantially parallel to and flush with the inner surface 206a of wall 206, thereby allowing the flow of current following neutral current return path 551 to substantially match that of current following neutral current return paths 293A, 293B. This maintains the electrical symmetry of the chamber and avoids generation of unwanted magnetic fields. Features in the chamber, such as a slit valve opening or view window, are prevented from diverting neutral currents in a way that generates unwanted magnetic fields.

Alternatively, multiple conductive shutters may be used to create neutral current bypass paths around multiple magnetic field-generating features in the chamber. For example, in addition to slit valve opening 290, other features in the chamber, such as view window 555 illustrated in FIG. 5, may divert neutral currents in a way that generates unwanted magnetic fields. Compared to most other features in a large-area substrate PECVD chamber that may generate a magnetic field, slit valve opening 290 is generally significantly larger and by far the biggest contributor to film non-uniformity. As substrate sizes increase, however, other neutral current-diverting features may begin to impact film uniformity and require a conductive shutter to create a neutral current bypass path. One example of an additional conductive shutter 552 is illustrated in FIG. 5. Additional conductive shutter 552 is shown after being placed in position over view window 555 prior to substrate processing. In placing additional conductive shutter 552 over window 555 and by establishing sound electrical contact at locations 552a and 552b, neutral current bypass path 553 is created. As described above, the presence of neutral current bypass path 553 reduces any unwanted magnetic field generated by view window 555.

In one aspect, conductive shutter 550 also acts as a slit valve door, creating a vacuum-tight seal between lower chamber 209 and slit valve opening 290. This isolates processing chamber 502 and transfer chamber 203, obviating the need for slit vale door 292. To create a vacuum-tight seal that does not unduly increase the resistivity of neutral current bypass path 551, conductive shutter 550 may include a conductive elastomeric contact surface, such as a metal-impregnated, elastomeric O-ring.

One advantage of creating a neutral current bypass path is that the root cause of film non-uniformity, i.e. neutral current flow through a magnetic field-generating feature in the chamber, is addressed directly and requires no changes to process parameters or other process tuning.

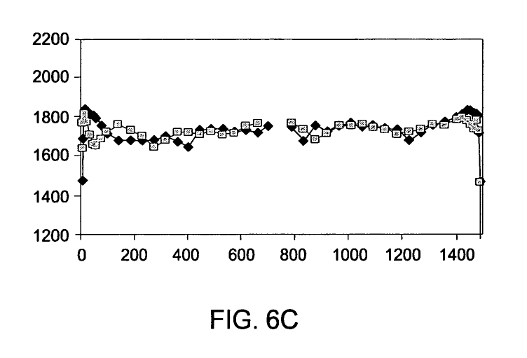

Table 3 summarizes film property and thickness non-uniformity data demonstrating the beneficial effect of a conductive shutter covering a slit valve opening during processing, as described above in conjunction with FIG. 5. The data for three 1300 mm×1500 mm substrates, substrates A, B, and C, are included in Table 3. FIGS. 6A, 6B, and 6C are graphs of the film thickness data measured along each diagonal of the substrates A, B, and C, respectively, i.e. each figure contains two data sets: one for each diagonal. For FIGS. 6A-6C, the abscissa represents the thickness measurement location along the diagonal of the substrate, i.e. between 0 mm to 1500 mm. The ordinate for FIGS. 6A-6C represents the equivalent deposition rate, in angstroms per minute, of a SiN film deposited on each respective substrate.

TABLE 3
Comparison of film properties and non-uniformity of three SiN films.

| | | | | Si—H | Non- |
|---|---|---|---|---|---|
| | | RF Power | Film Stress | Conc. | Uniformity |
| Substrate | Shutter | (kW) | (E9 dyne/cm²) | (%) | (%) |
| A | NO | 10 | −5.4 | 2.2 | 10.5 |
| B | YES | 10 | −6.9 | 1.7 | 7.8 |
| C | YES | 14 | −10.4 | 1.1 | 6.4 |

For ease of comparison, the process parameters for substrates A, B, and C were held constant for this test with the exception of RF power; substrates A and B were processed at 10 kW and substrate C was processed at 14 kW. All other parameters were held constant, including process gas flow, chamber pressure, diffuser plate-to-substrate support spacing, substrate temperature and deposition time. Further, the same chamber was used for processing substrates A-C. Substrate A was processed in the chamber with no conductive shutter deployed. Substrates B and C were processed in the chamber with a conductive shutter deployed over the slit valve opening. It is important to note, however, that the electrical contact between the conductive shutter and the inner surfaces of the chamber was marginal; for testing purposes, the shutter consisted of an aluminum plate resting over the slit valve opening. The shutter was not fastened or otherwise secured to the inner surfaces of the chamber. It is believed that a more robust installation of the conductive shutter, i.e. an installation incorporating a more substantial electrical connection to the inner surfaces of the chamber, will provide even more improvement in film non-uniformity.

Referring to Table 3, the film quality for all three substrates is satisfactory: Si—H content is low and compressive film stress is high. Thickness non-uniformity for substrate A is marginal, however, at 10.5%. Referring to FIG. 6A, the data sets for each thickness profile display the asymmetrical bulge 601 in thickness associated with an unwanted magnetic generated in the slit valve opening. Thickness non-uniformity for substrate B, which was processed with the conductive shutter deployed, is substantially better at 7.8%. To further test the robustness of the conductive shutter, substrate C was processing under identical conditions as substrate B, but at 14 kW—a significantly higher RF power. Referring to Table 3 and FIG. 6C, the film non-uniformity for substrate C, 6.4%, is even better than for substrate B despite the 4 kW increase in RF power. This indicates that the neutral current bypass path created by the conductive shutter has eliminated any noticeable effect of the slit valve opening on thickness uniformity. As noted above in conjunction with Table 2, on larger substrates, e.g. 2200 mm×1870 mm, thickness non-uniformity is strongly dependent on RF power. In one example, thickness non-uniformity increased from 10.8% to 14.0% for a SiN film when RF plasma power was only increased from 18 kW to 19 kW—a 1 kW increase. In contrast, the 4 kW increase in RF power between substrates B and C resulted in no degradation of film uniformity. Further, a chamber designed to process 2200 mm×1870 mm substrates has a perimeter 1.5 to 2 times as large as the chamber that processed substrates A-C. Hence, an increase in RF power in the smaller chamber produces a proportionately higher increase in neutral current density compared to the increase in neutral current density produced by an equal increase in RF power in the larger chamber. To wit, the 4 kW increase in RF power in the chamber used to process substrates 6A-C, i.e. the smaller chamber, will produce a change in neutral current density equivalent to a 6 kW to 8 kW increase in RF power in a chamber designed to process 2200 mm×1870 mm substrates. Therefore, the large increase in RF power between substrates B and C should create a significant difference in film non-uniformity. Since this was not the case, the presence of a bypass path for neutral current via the conductive shutter clearly eliminates the problem.

Regarding the data presented in Table 3 and FIGS. 6A-6C, it is important to note that film non-uniformity issues associated with the slit valve opening are only marginally noticeable with substrates of this size. As noted above in conjunction with Table 2, for larger substrates, i.e. on the order of 2200 mm×1870 mm, the non-uniformity proximal to the slit valve opening is significantly higher, i.e., on the order of about 30%. Therefore, it is believed that the film uniformity benefit of a conductive shutter will be substantially greater for these larger substrates.

In another embodiment, the lower chamber is extended in order to distance the slit valve opening from the process cavity. FIG. 7 illustrates a schematic cross-sectional view of a PECVD processing chamber, processing chamber 702, in which the lower chamber 209 is extended a distance 703 from the substrate support assembly 238. By distancing processing cavity 212 from the slit valve opening 290, the effects of any unwanted magnetic fields generated therein are reduced or eliminated. Preferably, the distance 703 is at least about 40% of the characteristic length of the diffuser plate 258.

Although several preferred embodiments which incorporate the-teachings of the present invention have been shown and described in detail, those skilled in the art can readily devise many other varied embodiments that still incorporate these teachings.

While the foregoing is directed to embodiments of the present invention, other and further embodiments of the invention may be devised without departing from the basic scope thereof, and the scope thereof is determined by the claims that follow.

1. A method of depositing a thin film on a large-area substrate, comprising:
placing a substrate on a substrate support mounted in a processing cavity of a processing chamber, wherein the chamber comprises:
at least one magnetic field-generating;
at least one region in the processing cavity wherein plasma is substantially affected by the at least one magnetic field-generating feature and
a diffuser plate comprising a plurality of gas passages;
flowing a process fluid through a diffuser plate toward the substrate supported on the substrate support, wherein the diffuser plate is adapted to alter the plasma density in the at least one region in the processing cavity as required to obtain a desired film uniformity; and
creating a plasma between the diffuser plate and the substrate support.

2. The method of claim 1, wherein the at least one magnetic field-generating feature is selected from the group consisting of a slit valve opening, a view window, and a combination of both.

3. The method of claim 1, wherein the diffuser plate is asymmetrically extended to increase process fluid flow to the at least one region to obtain a desired film uniformity.

4. The method of claim 1, wherein the conductance profile of the gas passages is asymmetrical as required to increase process fluid flow to the at least one region in the chamber to obtain a desired film uniformity.

5. The method of claim 1, wherein the at least one magnetic field-generating feature is a slit valve opening and the diffuser plate is asymmetrically extended between about 30% and about 40% of the characteristic length of the diffuser plate to obtain a desired film uniformity.

6. The method of claim 5, wherein the thin film is a SiN film.

7. The method of claim 1, wherein:
the at least one magnetic field-generating feature is a slit valve opening;
the thin film is a SiN film;
the plurality of gas passages comprise hollow cathode cavities; and
the hollow cathode cavities corresponding to the at least one region in the processing cavity are reduced in surface area, volume, or density to obtain a desired film uniformity.

8. A method of depositing a thin film on a large-area substrate, comprising:
placing a substrate on a substrate support mounted in a processing cavity of a processing chamber, wherein the chamber comprises:
an inner wall;
at least one magnetic field-generating feature;
at least one region in the processing cavity wherein plasma is substantially affected by the at least one magnetic field-generating feature; and
a diffuser plate comprising a plurality of gas passages;
creating a neutral current bypass path after placing the substrate on the substrate support and prior to creating a plasma, wherein the neutral current bypass path substantially reduces neutral current flow through the at least one magnetic field-generating feature;
flowing a process fluid through a diffuser plate toward the substrate supported on the substrate support; and
creating a plasma between the diffuser plate and the substrate support.

9. The method of claim 8, wherein the resistivity of the neutral current bypass path is substantially less than the neutral current path through the magnetic field-generating feature.

10. The method of claim 9, wherein:
the at least one magnetic field-generating feature is a penetration of the inner wall selected from the group consisting of a slit valve opening, a view window, and a combination of both; and
the process of creating a neutral current bypass path comprises covering the magnetic field-generating feature with a conductive shutter that is substantially parallel to and flush with the inner wall.

11. The method of claim 10, wherein the conductive shutter is also a vacuum-tight slit valve door.

12. The method of claim 8, wherein the thin film is a SiN film.

13. A method of making a plasma-processing chamber for a large area substrate electrically symmetric during processing, comprising:
providing a plasma-processing chamber for large area substrates, wherein the chamber comprises:
an inner wall; and
at least one magnetic field-generating feature; and
creating a neutral current bypass path, wherein the neutral current bypass path substantially reduces neutral current flow through the at least one magnetic field-generating feature.

14. The method of claim 13, wherein:
the at least one magnetic field-generating feature is a slit valve opening; and
the process of creating a neutral current bypass path comprises covering the magnetic field-generating feature with a conductive shutter that is substantially parallel to and flush with the inner wall.

15. The method of claim 14, wherein the conductive shutter is also a vacuum-tight slit valve door.

16. A plasma-processing chamber for large-area substrates, comprising:
a processing cavity;
an inner wall;
at least one magnetic field-generating feature;
at least one region in the processing cavity wherein plasma is substantially affected by the at least one magnetic field-generating feature;
a diffuser plate comprising a plurality of gas passages, wherein the diffuser plate is asymmetrically adapted to alter the plasma density in the at least one region in the processing cavity as required to obtain a desired film uniformity.

17. The plasma-processing chamber of claim 16, wherein the at least one magnetic field-generating feature is selected from the group consisting of a slit valve opening, a view window, and a combination of both.

18. The plasma-processing chamber of claim 16, wherein the asymmetrically adapted diffuser plate comprises an asymmetrical extension to the diffuser plate to obtain a desired film uniformity.

19. The plasma-processing chamber of claim 16, wherein the conductance profile of the gas passages is configured asymmetrically as required to increase process fluid flow to the at least one region in the chamber to obtain a desired film uniformity.

20. The plasma-processing chamber of claim 16, wherein the at least one magnetic field-generating feature is a slit valve opening and the diffuser plate is asymmetrically extended between about 30% and about 40% of the characteristic length of the diffuser plate to obtain a desired film uniformity.

21. The method of claim 16, wherein:
the at least one magnetic field-generating feature is a slit valve opening;
the thin film is a SiN film;
the plurality of gas passages comprise hollow cathode cavities; and
the hollow cathode cavities corresponding to the at least one region in the processing cavity are reduced in surface area, volume, or density to obtain a desired film uniformity.

22. A conductive shutter for a plasma-processing chamber, a conductive body adapted to create a neutral current bypass path around a magnetic field-generating feature; and
an actuator.

23. The conductive shutter of claim 22, wherein the electrical resistivity of a neutral current bypass path formed therewith is substantially less than the electrical resistivity of a neutral current path through the magnetic field-generating feature.

24. The conductive shutter of claim 22, wherein the magnetic field-generating feature is a slit valve opening.

25. The conductive shutter of claim 24, wherein the conductive shutter is further adapted to establish a vacuum-tight seal over the slit valve opening.

26. A plasma-processing chamber for large-area substrates, comprising:
a processing cavity defined by a diffuser plate and a substrate support; and
a lower chamber region defined by at least one inner wall, the substrate support, and a chamber floor, comprising:
a first portion located proximate the processing cavity;
a distal portion located adjacent the first portion and a significant distance from the processing cavity; and
a magnetic field-generating feature located in the distal portion.

27. The plasma-processing chamber of claim 26, wherein the magnetic field-generating feature is a slit valve opening.

28. The plasma-processing chamber of claim 27, wherein the significant distance is at least about 40% of the characteristic length of the diffuser plate.
